(19) United States
(12) Patent Application Publication
(10) Pub. No.: US 2001/0011828 A1
(43) Pub. Date: Aug. 9, 2001

(54) SPHERICAL PARTICLE TRANSPORT APPARATUS

(76) Inventors: JUNICHI UJITA, SAITAMA (JP); HIROSHI SUZUKI, TOKYO (JP)

Correspondence Address: ROBERT W. J. USHER, PATENT AGENT, 1133 BROADWAY, #1515, NEW YORK, NY, 10010

(21) Appl. No.: 09/184,563

(22) Filed: Nov. 2, 1998

(30) Foreign Application Priority Data
Dec. 9, 1997 (JP) 9-338353

(51) Int. Cl. B23K 26/00; B23P 21/00; H01L 21/60

(52) U.S. Cl. 294/64.1

(57) ABSTRACT

A pick-up device 10 sucks the air through a suction port 13, which is provided at the lower end of a capillary 12 and thereby picks up a solder ball H with the lower end of the capillary 12. Then, the pick-up device 10 transports the solder ball H to an electrical terminal of an electronic component IC and mounts it on the terminal. An air blower 20 is provided below the route which the pick-up device 10 takes for the transportation. During the transportation of the solder ball H, the capillary 12 of the pick-up device 10 is exposed to the air which is blown upward from the air blower 20, so the extra solder balls which have stuck to the periphery of the capillary 12 are blown off from the capillary 12. Because the direction of the air being blown is vertically upward, the solder ball H stuck in the suction port 13 of the capillary 12 is pushed to the suction port 13 and is firmly retained there.

### FIELD OF THE INVENTION

The present invention generally relates to an apparatus which is used for transporting spherical particles such as solder balls used in ball grid array (BGA) and flip chip technologies and particularly to a spherical particle transport apparatus which is used for transporting solder balls to predetermined locations where an electronic component like an IC chip is surface mounted.

### BACKGROUND OF THE INVENTION

Nowadays, circuit boards on which electrical components such as IC chips are surface mounted are experiencing miniaturization, requiring electrical components to be made thinner and thinner in low profiles. The above mentioned BGA and flip chip technologies are known as electrical connection technologies to meet such demand and are applied to surface mount miniaturized electronic components. The electrical terminals which are provided on the lower face of each electronic component are supplied with solder balls at first. Then, each electronic component is placed at a predetermined location on a circuit board onto which these electronic components are surface mounted. With these solder balls of the electronic components being attached to the respective terminals which are provided as circuit patterns on the circuit board, the whole unit of this assembly is passed through a heating furnace to fuse the solder balls and to glue the respective terminals between the electronic components and the circuit board.

Now, the attachment of solder balls to each electronic component in BGA and flip chip connection is described more in detail. The attachment of all the solder balls to the terminals of each electronic component is completed in a single process by a pick-up machine which is designed for mass production. In this process, however, a failure may happen in which some solder balls fail to attach to the terminals of the electronic components. Thus, it is necessary to perform an inspection and some repair work (supplementary work).

A pick-up device 50 which is used for the above mentioned repair work is shown in FIG. 6. This pick-up device 50 comprises a pick-up head 51 and a capillary 52 which extends downward from the pick-up head 51. In addition, a suction port is provided at the lower end of the capillary 52. This suction port is so designed that it can picked up only a single solder ball, so the pick-up device 50 picks up and transports only one solder ball in a single process.

The picking up of the solder ball is carried out first by inserting the capillary 52 into a container in which a plurality of solder balls are placed. In this instance, the air is sucked from the suction port (i.e., a negative pressure is created at the suction port) to suck a solder ball into the suction port. This suction is intended for the picking up of only one solder ball. However, some other solder balls are likely to stick onto the periphery of the capillary 52 because of the static electricity present, as shown in the figure. To remove such unwanted extra balls, the pick-up head 51 incorporates a vibrator 55, which is activated by a power source 60. This vibrator 55 is activated to produce an ultrasound and thereby a vibration in the capillary 52 to drop off these extra solder balls.

This method for removing or dropping off unwanted solder balls by a vibration has been successful for solder balls which are formed with relatively large diameters (700 μm-1000 μm). However, nowadays, solder balls are being made smaller and smaller (e.g., 70 μm) to realize high density assembly, and the removing of such small solder balls by an ultrasonic vibration is becoming difficult.

Besides, this pick-up device 50, which incorporates the vibrator 55 in the pick-up head and requires the power source 60 for the generation of an ultrasound, is complex in design and expensive to produce.

### SUMMARY OF THE INVENTION

It is an object of the present invention to provide a spherical particle transport apparatus which enables and ensures one by one transportation of solder balls even though the balls are very small (i.e., spherical particles).

It is another object of the present invention to provide a spherical particle transport apparatus which is capable of blowing off unwanted extra solder balls that stick to the periphery of a pick-up device when the pick-up device picks up a solder ball one by one.

In order to attain these objectives, the present invention provides a spherical particle transport apparatus which comprises a pick-up device and an air blower. The pick-up device has a suction port in the lower end face thereof, through which the pick-up device sucks the air to pick up and transport a solder ball one at a time, and these solder balls are used in BGA or flip chip technology for establishing electrical connection. The air blower blows air to the pick-up device to drop off extra solder balls which have stuck to the periphery of the pick-up device, while keeping the solder ball which is sucked in the suction port.

For example, the pick-up device comprises a capillary which is formed of a tubular member and which extends downward, and the pick-up device sucks the air through this capillary. An opening is provided at the lower end of the capillary, and this opening represents the above mentioned suction port. With this construction, the pick-up device is capable of picking up one solder ball singularly. In this case, the air blower blows air to the lower end of the capillary to drop off the extra solder balls which are sticking to the capillary while the solder ball which is sucked in the suction port is retained unaffected.

This design of the present invention is different from a method in which a vibration is applied to drop off unwanted solder balls. By the blowing of air, a relatively large direct external force is applied to each of the extra solder balls which are sticking to the pick-up device, and these solder balls are dropped off. In this instance, as the solder ball which is stuck in the suction port is being sucked and retained therein, there is no fear of dropping off of this solder ball. In other words, the strength of the air blown from the air blower is adjusted so as to blow off only the extra solder balls and to retain firmly the solder ball which is sucked in the suction port.

It is preferable that this apparatus be designed such that the retaining of the solder ball in the suction port is assisted by the blowing of air. In this case, the flow of the air is directed perpendicularly to the plane in which the suction port meets with the solder ball, so that the blowing of air pushes the solder ball into the suction port. With this design, the solder ball, which is sucked in the suction port, is firmly retained in the suction port, and there is no possibility of the solder ball being blown off by the air which is applied to drop off the unwanted extra solder balls.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only and thus are not limitative of the present invention and wherein:

FIG. 1 is a side view of a spherical particle transport apparatus which is constructed in accordance with the present invention;

FIG. 2A is a perspective view of a pick-up machine for mass production, which shows the mounting of solder balls to an IC chip;

FIG. 2B is a perspective view of the IC chip with the solder balls;

FIG. 3 is a perspective view of a production line, in which IC chips attached with solder balls H by the pick-up machine are inspected and repaired if necessary;

FIG. 4 is an enlarged view of an air blower and the lower end of an capillary, which shows the direction of the air flow;

FIG. 5 is a perspective view of a circuit board and a few IC chips which are connected in BGA; and

FIG. 6 is a side view of a pick-up device of prior art which is used for repair work.

### DESCRIPTION OF THE PREFERRED EMBODIMENTS

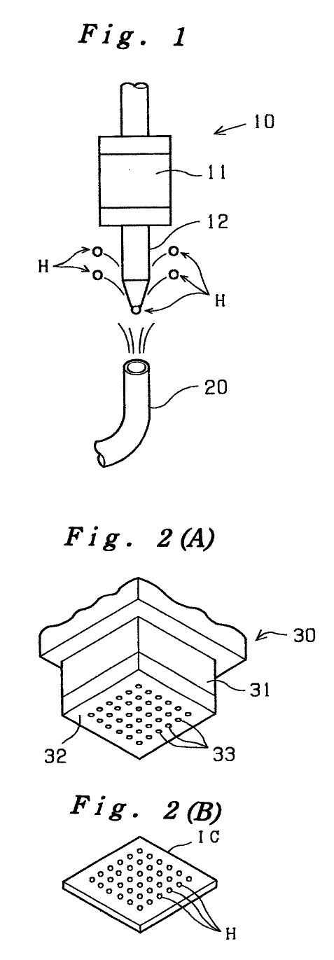

FIG. 2B shows an electronic component IC which is to be electrically connected in BGA, with the lower face of the electronic component IC being turned upward. A plurality of electrical terminals are provided on the lower face of the electronic component IC, and a number of solder balls H (about 200 to 1,000) are attached to these terminals. In this embodiment, each of the solder balls is formed of a solder in a spherical shape with a diameter of about 70 μm.

Now, the mounting of such solder balls H to an electronic component IC is described in detail. As shown in FIG. 2, the solder balls H are mounted by using a pick-up device 30, which comprises a pick-up head 31 having a plurality of suction ports 33 in the lower face 32 thereof. The pick-up device 30 sucks the air through these suction ports 33 and thereby picks all the solder balls H which are to be mounted onto the electronic component IC in a single process.

Then, the pick-up device 30 transports these solder balls H, which are stuck in the lower face 32 of the pick-up head 31, to the lower face of the electronic component IC, and the pick-up device 30 pushes the solder balls onto the electrical terminals of the electronic component IC and then stops the suction of the air. Because these terminals are coated with a sticky flux, these solder balls H stick to the respective terminals.

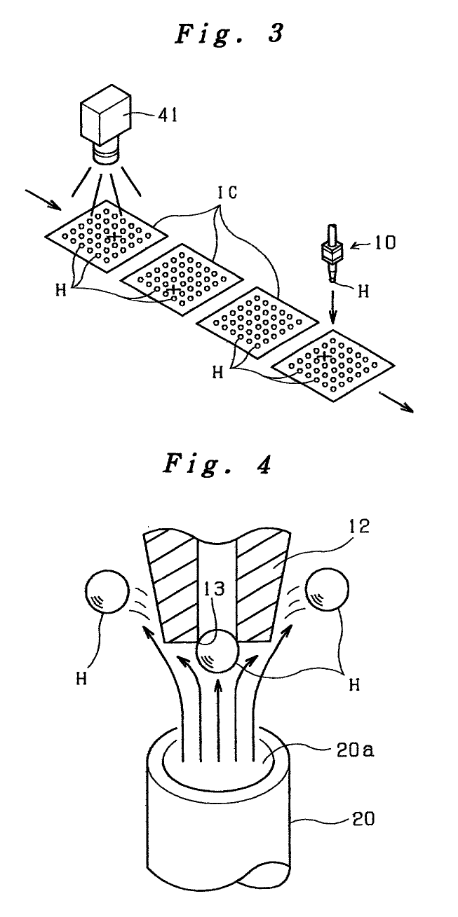

As shown in FIG. 3, the electronic components IC, which are provided with the solder balls H, are then moved by a conveyor to a location where the grid array of the solder balls attached on each electronic component IC is inspected by an image processor 41 whether there is any failure in the mounting of the solder balls. If there is no failure, then the electronic components IC are continuously conveyed. However, if there is a failure, i.e., a vacancy in the BGA, then, into this very vacancy (indicated with “X” in the figure), a supplementary solder ball H is provided by a repair pick-up 10.

As shown in FIG. 1, the repair pick-up 10 comprises a pick-up head 11 and a capillary 12, which extends vertically downward from the lower end of the pick-up head 11. The capillary 12 is formed of a tubular member whose lower portion is squeezed or tapered gradually downward, and the lower end of the capillary 12 is open to suck the air.

This repair pick-up 10 is fabricated such that only a single solder ball H sticks into the opening 13 (this opening is hereinafter referred to as “suction port”) which is provided at the lower end of the capillary 12 (see FIG. 4). The lower end of the capillary 12, which is the site of the suction, is horizontal to optimize the sticking of the solder ball H as shown in FIG. 4.

In the repair process, at first, while the repair pick-up 10 is sucking the air through the suction port 13, the capillary 12 is put into a container which is filled with solder balls H, to pick up a solder ball H. Then, the repair pick-up 10 with the solder ball H stuck in the suction port 13 is moved to a location where there is a vacancy in the array of solder balls on an electronic component IC, and the solder ball H which is brought by the repair pick-up 10 is placed into the vacancy. During the pick-up process, extra solder balls H may stick to the periphery of the capillary 12. To drop off such extra solder balls H from the capillary 12, the repair pick-up 10 after picking up a single solder ball H is blown with the air supplied from an air blower 20 (see FIG. 1) at a certain position while the repair pick-up 10 is transporting the solder ball H for the repair of the BGA.

This air blower 20 is provided at a certain location in the route of the repair pick-up 10, and it blows air upward to the capillary 12. By the blowing of air, a relatively large direct external force can be applied to extra solder balls H sticking to the periphery of the capillary 12. Such external force is not achievable by the vibration of the capillary 12, which is practiced in prior art. in the present invention, because of the blowing of air, even such small solder balls H as described in this embodiment can be dropped off smoothly from the periphery of the capillary 12. The blowing of air to the capillary 12 can be realized by placing and stopping the repair pick-up 10 directly above the air blower 20 even while the repair pick-up 10 is continuously moving.

As shown in FIG. 4, the repair pick-up 10 transports the solder ball H picked up in the suction port 13 to pass directly above the outlet 20a of the air blower 20. When the suction port 13 of the capillary 12 facing downward is moved above the outlet 20a, the air blower 20 blows the air vertically upward.

As mentioned previously, because the suction port 13 is provided horizontally, the solder ball H which is stuck in the suction port 13 is firmly retained therein, receiving an additional upward pressure when the air is blown upward. On the other hand, as the periphery of the capillary 12 is uniformly exposed to the blowing, the extra solder balls H sticking to the periphery are completely blown off.

After this blowing, an inspection is carried out by an image recognizing device (not shown in the figure, which is different from the above mentioned image processor 41) to determine whether a solder ball H is present in the suction port 13 and whether there is any extra solder ball H sticking to the capillary 12.

If the conditions that there is an solder ball H in the suction port 13 and that no extra solder ball H is sticking to the capillary 12 are ascertained from the detection made by the image recognizing device, then the repair pick-up 10 continues the transportation of the solder ball H to the location of the vacancy in the BGA. After reaching the location, the repair pick-up 10 places and pushes the solder ball onto the respective terminal of the electronic component IC. Then the suction of the air is stopped, and the mounting of the solder ball H into the vacancy is completed. On the other hand, if no solder ball H is detected in the suction port 13, then the above mentioned pick-up process is repeated from the beginning. Furthermore, if any extra solder ball H is detected to be still sticking after the blowing, then the blowing process is repeated.

After this repair work is complete, the lower face of the electronic component IC on which these solder balls H are mounted is turned downward. Then, this electronic component IC with the solder balls H is placed on a circuit board (not shown) at a location where respective circuit terminals are provided to receive the electronic component IC. After repeating and finishing the same process for all the electronic components IC, this circuit board with the electronic components IC is taken into a furnace (i.e., a heating path), and when the solder balls H melt, the respective electronic components IC are surface mounted on the circuit board.

Even though the above mentioned blowing is described for the repair pick-up 10, this air blowing can be also applied to the pick-up device 30, which is designed for mass production. In this case, the air is blown upward to the lower face 32 of the pick-up device 30 to drop off the extra solder balls H which are sticking to the pick-up head 31.

In addition to the above embodiment, in which the spherical particle transport apparatus of the present invention is described for use in BGA technology with solder balls, the spherical particle transport apparatus of the present invention can be also applied to a BGA technology which uses gold solder balls as spherical electrical terminals. Furthermore, the spherical particle transport apparatus of the present invention can be used for the transportation of solder balls not only in BGA connection but also in flip chip connection.

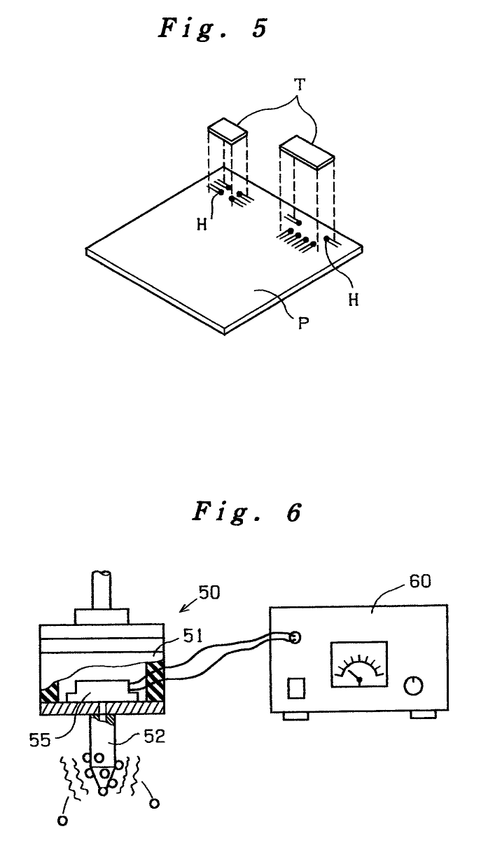

In the above embodiment, the repair pick-up 10 is used for the repairing. However, if a few electronic components are to be mounted on a circuit board in a variety of ways for a production of a relatively small number of circuit boards, for example, IC chips T each requiring a relatively small number (less than 20) of solder balls are to be mounted on a circuit board P in BGA connection as shown in FIG. 5, then the repair pick-up 10 can be used not only for the repairing work, but also for the original mounting. In this case, the mounting of solder balls H onto the electrical terminals of the electronic component IC is carried out in one solder ball by one solder ball transportation with a device which is similar to the repair pick-up 10 described in the above embodiment.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

### RELATED APPLICATIONS

This application claims the priority of Japanese Patent Application No.09-338353 filed on Dec. 9, 1997, which is incorporated herein by reference.

What is claimed is:

1. A spherical particle transport apparatus comprising:
a pick-up device having a suction port on a lower end face thereof, through which air is sucked, said pick-up device sucking a spherical particle with said suction port to transport said spherical particle; and
an air blower which blows air to said pick-up device to drop off extra spherical particles which have stuck to said pick-up device while said spherical particle is retained in said suction port.

2. The spherical particle transport apparatus set forth in claim 1 wherein:
said pick-up device includes a capillary formed of a tubular member which extends downward with an opening at a lower end thereof, said opening comprising said suction port, said air being sucked through said capillary; and
said spherical particle is singly sucked and retained in said opening.

3. The spherical particle transport apparatus set forth in claim 2 wherein:
an air flow from said air blower is directed perpendicular to a surface where a solder ball is sucked; and
said solder ball, which is sucked in said suction port, is pushed to said suction port by the air blown from said air blower.

4. The spherical particle transport apparatus set forth in claim 1 wherein:
said spherical particle is a solder ball which is used for electrical connection in BGA or flip chip.

5. The spherical particle transport apparatus set forth in claim 1 wherein:
said spherical particle is a gold ball used as electrodes in BGA connection.

6. The spherical particle transport apparatus set forth in claim 1 wherein:
said air blower is provided in a transportation route which is taken by said pick-up device.

7. The spherical particle transport apparatus set forth in claim 6 wherein:
when said pick-up device moves along said transportation route, said pick-up device passes above said air blower so that the air blown upward from said air blower hits the lower face of said pick-up device.

8. The spherical particle transport apparatus set forth in claim 1 wherein:
said apparatus is a repair pick-up device which is constructed with a single suction port in the lower face of said pick-up device so that said spherical particle is picked up and transported one by one.

9. The spherical particle transport apparatus set forth in claim 1 wherein:
said apparatus is a mass manufacturing pick-up device which is constructed with a plurality of suction ports in the lower face of said pick-up device so that a plurality of said spherical particles are picked up and transported in a single process.
